(19) United States
(12) Patent Application Publication
(10) Pub. No.: US 2025/0201712 A1
(43) Pub. Date: Jun. 19, 2025

(54) ETCH STOP LAYER FOR BACKSIDE POWER DELIVERY NETWORK

(71) Applicant: International Business Machines Corporation, Armonk, NY (US)

(72) Inventors: Alexander Reznicek, Troy, NY (US); Sagarika Mukesh, Albany, NY (US); Tsung-Sheng Kang, Ballston Lake, NY (US); Ruilong Xie, Niskayuna, NY (US)

(21) Appl. No.: 18/541,370

(22) Filed: Dec. 15, 2023

(51) Int. Cl. H01L 23/528; H01L 27/088; H01L 29/06; H01L 29/417; H01L 29/423; H01L 29/775; H01L 29/786

(52) U.S. Cl. CPC H01L 23/5286; H10D 30/43; H10D 30/6735; H10D 30/6757; H10D 62/121; H10D 64/254; H10D 84/83

(57) ABSTRACT

A semiconductor structure includes a first semiconductor fin disposed on a first source/drain region of a first nanosheet transistor device, a second semiconductor fin disposed on a second source/drain region of a second nanosheet transistor device, a first dielectric etch stop layer disposed on the first semiconductor fin, and a second dielectric etch stop layer disposed on the second semiconductor fin. The first semiconductor fin and the second semiconductor fin are of a uniform height.

### BACKGROUND

Generally, semiconductor devices can include a plurality of circuits which form an integrated circuit fabricated on a substrate. A complex network of signal paths can be routed to connect the circuit elements distributed on the surface of the substrate. Efficient routing of these signals can include the formation of multilevel or multilayered schemes (e.g., single or dual damascene wiring structures) during the back-end-of-line (BEOL) phase of manufacturing. Within an interconnect structure, conductive vias can run perpendicular to the substrate and conductive lines can run parallel to the substrate.

### SUMMARY

Illustrative embodiments of the present application include techniques for use in semiconductor manufacture. In an illustrative embodiment, a semiconductor structure comprises a first semiconductor fin disposed on a first source/drain region of a first nanosheet transistor device, a second semiconductor fin disposed on a second source/drain region of a second nanosheet transistor device, a first dielectric etch stop layer disposed on the first semiconductor fin, and a second dielectric etch stop layer disposed on the second semiconductor fin. The first semiconductor fin and the second semiconductor fin are of a uniform height.

The semiconductor structure of the illustrative embodiment advantageously uses a dielectric etch stop layer that exhibits a superb etch selectivity against crystalline silicon, and is thermally stable so it will not diffuse into a silicon substrate. The dielectric etch stop layer can have a predetermined uniform thickness thereby allowing the total height of the silicon fin to be smaller. This, in turn, provides advantages to metal via like structures (e.g., a shorter metal via results in an improved aspect ratio).

In one or more additional illustrative embodiments, as may be combined with the preceding paragraphs, the first semiconductor fin and the first dielectric etch stop layer have a same width, and the second semiconductor fin and the second dielectric etch stop layer have a same width.

In one or more additional illustrative embodiments, as may be combined with the preceding paragraphs, the first dielectric etch stop layer and the second dielectric etch stop layer each comprises a buried oxide layer.

In one or more additional illustrative embodiments, as may be combined with the preceding paragraphs, the first dielectric etch stop layer and the second dielectric etch stop layer each comprises an epitaxial oxide layer.

In one or more additional illustrative embodiments, as may be combined with the preceding paragraphs, the first semiconductor fin and the second semiconductor fin comprise a first backside silicon fin and a second backside silicon fin.

In one or more additional illustrative embodiments, as may be combined with the preceding paragraphs, the semiconductor structure further comprises a middle-of-the-line contact disposed on a given one of the first source/drain region and the second source/drain region, and a metal via connecting a backside power rail to the middle-of-the-line contact.

In one or more additional illustrative embodiments, as may be combined with the preceding paragraphs, the semiconductor structure further comprises a backside power delivery network disposed over the backside power rail.

In another illustrative embodiment, a semiconductor structure comprises a first silicon fin disposed on a first source/drain region of a first nanosheet transistor device, a second silicon fin disposed on a second source/drain region of a second nanosheet transistor device, a first dielectric etch stop layer disposed on the first silicon fin, and a second dielectric etch stop layer disposed on the second silicon fin. The first silicon fin and the second silicon fin are disposed between adjacent shallow trench isolation regions. The first silicon fin and the second silicon fin are of a uniform height.

The semiconductor structure of the illustrative embodiment advantageously uses a dielectric etch stop layer that exhibits a superb etch selectivity against crystalline silicon, and is thermally stable so it will not diffuse into a silicon substrate. The dielectric etch stop layer can have a predetermined uniform thickness thereby allowing the total height of the silicon fin to be smaller. This, in turn, provides advantages to metal via like structures (e.g., a shorter metal via results in an improved aspect ratio).

In one or more additional illustrative embodiments, as may be combined with the preceding paragraphs, the first dielectric etch stop layer is a first lattice matched etch stop layer and the second dielectric etch stop layer is a second lattice matched etch stop layer.

In one or more additional illustrative embodiments, as may be combined with the preceding paragraphs, the first silicon fin and the second silicon fin are each epitaxially grown on the first lattice matched etch stop layer and the second lattice matched etch stop layer.

In one or more additional illustrative embodiments, as may be combined with the preceding paragraphs, the first lattice matched etch stop layer comprises a first epitaxial oxide layer and the second lattice matched etch stop layer comprises a second epitaxial oxide layer.

In one or more additional illustrative embodiments, as may be combined with the preceding paragraphs, the first epitaxial oxide layer and the second epitaxial oxide layer each comprises a layer of a mixed rare earth oxide, the mixed rare earth oxide being single crystal and lattice-matched to the first silicon fin and the second silicon fin.

In one or more additional illustrative embodiments, as may be combined with the preceding paragraphs, the mixed rare earth oxide comprises a compound having a chemical formula (AₓB₁₋ₓ)₂O₃, wherein A represents a first rare earth element and B represents a second rare earth element.

In one or more additional illustrative embodiments, as may be combined with the preceding paragraphs, the mixed rare earth oxide comprises (Laₓ Y₁₋ₓ)₂O₃ and x is 0.33.

In one or more additional illustrative embodiments, as may be combined with the preceding paragraphs, the first silicon fin and the second silicon fin comprise a first backside silicon fin and a second backside silicon fin.

In one or more additional illustrative embodiments, as may be combined with the preceding paragraphs, the semiconductor structure further comprises a middle-of-the-line contact disposed on a given one of the first source/drain region and the second source/drain region, and a metal via connecting a backside power rail to the middle-of-the-line contact.

In one or more additional illustrative embodiments, as may be combined with the preceding paragraphs, the semiconductor structure further comprises a backside power delivery network disposed over the backside power rail.

Another exemplary embodiment comprises an integrated circuit comprising one or more semiconductor devices. At least one of the one or more semiconductor devices is a semiconductor device according to one or more of the foregoing illustrative embodiments.

The integrated circuit of the illustrative embodiment advantageously allows for semiconductor structures that use a dielectric etch stop layer which exhibits a superb etch selectivity against crystalline silicon, and is thermally stable so will not diffuse into the silicon substrate. The dielectric etch stop layer can have a predetermined uniform thickness thereby allowing the total height of the silicon fin to be smaller. This, in turn, provides advantages to metal via like structures (e.g., a shorter metal via results in an improved aspect ratio).

Other embodiments will be described in the following detailed description of embodiments, which is to be read in conjunction with the accompanying figures.

### BRIEF DESCRIPTION OF THE DRAWINGS

FIG. 1 depicts a cross sectional view illustrating a semiconductor structure during an intermediate step of a method of fabricating a nanosheet transistor structure, according to an illustrative embodiment.

FIG. 2 depicts a cross-sectional view illustrating the semiconductor structure following growing a semiconductor material on a semiconductor layer, according to an illustrative embodiment.

FIG. 3 depicts a cross-sectional view illustrating the semiconductor structure following the formation of nanosheets over the semiconductor layer, according to an illustrative embodiment.

FIGS. 4 and 5 depict a cross-sectional view illustrating the semiconductor structure following nanosheet patterning and formation of field-effect transistor (FET) stacks between adjacent shallow trench isolation regions, according to an illustrative embodiment.

FIG. 6 depicts a cross-sectional view illustrating the semiconductor structure following various front-end-of-line processing steps, according to an illustrative embodiment.

FIG. 7 depicts a cross-sectional view illustrating the semiconductor structure following the formation of a metal via and middle-of-the-line contacts in an interlevel dielectric (ILD) layer, according to an illustrative embodiment.

FIG. 8 depicts a cross-sectional view illustrating the semiconductor structure following formation of another ILD layer, followed by patterning and etching vias in the exposed ILD layer, according to an illustrative embodiment.

FIG. 9 depicts a cross-sectional view illustrating the semiconductor structure following formation of a frontside back-end-of-line interconnect and a carrier wafer, according to an illustrative embodiment.

FIG. 10 depicts a cross-sectional view illustrating the semiconductor structure following backside processing of the semiconductor structure and removal of a substrate, according to an illustrative embodiment.

FIG. 11 depicts a cross-sectional view illustrating the semiconductor structure following the removal of an etch stop layer, according to an illustrative embodiment.

FIG. 12 is a cross-sectional view illustrating the semiconductor structure following formation of a backside ILD layer and backside power rails, according to an illustrative embodiment.

FIG. 13 is a cross-sectional view illustrating the semiconductor structure following the formation of a backside power delivery network, according to an illustrative embodiment.

FIG. 14 is a cross-sectional view of a semiconductor structure during an intermediate step of a method of fabricating a nanosheet transistor structure according to an illustrative alternative embodiment.

FIG. 15 is a cross-sectional view illustrating the semiconductor structure following the formation of a lattice matched etch stop layer on a substrate, according to an illustrative embodiment.

FIG. 16 depicts a cross-sectional view illustrating the semiconductor structure following growing a semiconductor material on the lattice matched etch stop layer according to the illustrative alternative embodiment.

FIG. 17 depicts a cross-sectional view illustrating the semiconductor structure following formation of nanosheets over the semiconductor layer, according to the illustrative alternative embodiment.

FIGS. 18 and 19 depict a cross-sectional view illustrating the semiconductor structure following nanosheet patterning and formation of FET stacks between adjacent STI regions, according to the illustrative alternative embodiment.

FIG. 20 depicts a cross-sectional view illustrating the semiconductor structure following various front-end-of-line processing steps, according to the illustrative alternative embodiment.

FIG. 21 depicts a cross-sectional view illustrating the semiconductor structure following the formation of a metal via and middle-of-the-line contacts in an ILD layer, according to the illustrative alternative embodiment.

FIG. 22 depicts a cross-sectional view illustrating the semiconductor structure following formation of another ILD layer, followed by patterning and etching vias in the exposed ILD layer, according to the illustrative alternative embodiment.

FIG. 23 depicts a cross-sectional view illustrating the semiconductor structure following formation of a frontside back-end-of-line interconnect and a carrier wafer, according to the illustrative alternative embodiment.

FIG. 24 depicts a cross-sectional view illustrating the semiconductor structure following backside processing of the semiconductor structure and removal of a substrate, according to the illustrative alternative embodiment.

FIG. 25 depicts a cross-sectional view illustrating the semiconductor structure following the removal of an etch stop layer, according to the illustrative alternative embodiment.

FIG. 26 depicts a cross-sectional view illustrating the semiconductor structure following formation of a backside ILD layer and backside power rails, according to the illustrative alternative embodiment.

FIG. 27 depicts a cross-sectional view illustrating the semiconductor structure following formation of a backside power delivery network, according to the illustrative alternative embodiment.

### DETAILED DESCRIPTION

This disclosure relates generally to semiconductor devices, and more particularly to a backside power distribution network (BSPDN) substrate formation using a lattice matched etch stop layer on a silicon substrate and methods for their fabrication. However, it is to be understood that embodiments of the invention are not limited to the illustrative methods, apparatus, systems and devices but instead are more broadly applicable to other suitable methods, apparatus, systems and devices.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

It is to be understood that the various layers, structures, and/or regions shown in the accompanying drawings are schematic illustrations that are not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

A field-effect transistor (FET) is a transistor having a source, a gate, and a drain, the operation of which depends on the flow of carriers (electrons or holes) along a channel that runs between the source and drain. Current through the channel between the source and drain may be controlled by a transverse electric field under the gate. FETs are widely used for switching, amplification, filtering, and other tasks.

Various techniques may be used to remove a silicon substrate when forming a backside power distribution network. For example, silicon germanium (SiGe) may be used as an etch stop layer. However, a SiGe layer is thermally unstable and the Ge can diffuse into the silicon fin when the semiconductor structure goes through multiple thermal cycles. In addition, an uneven recess of the silicon substrate when forming a backside power distribution network vias implies that the process assumption numbers must be increased to accommodate both the worst case of a silicon thickness and the thinnest silicon thickness. This will increase the backside connecting via height as well as make etching/metallizing tall vias and resistance concerns more challenging. While the ideal integration scheme would be to remove all silicon, it can have a high probability of damaging active devices.

Accordingly, illustrative embodiments described herein overcome the foregoing drawbacks. Advantages of the illustrative embodiments include that the deposition of a dielectric etch stop layer such as a relatively thin layer of an epitaxial oxide or a lattice matched etch stop layer onto a silicon substrate and allows for subsequent growth of a device quality epitaxial silicon such as a relatively thick layer of device quality epitaxial silicon. Other advantages include that the dielectric etch stop layer or dielectric lattice matched etch stop layer exhibits a superb etch selectivity against crystalline silicon, and is thermally stable so it will not diffuse into the silicon substrate as compared to SiGe. Still other advantages include that the dielectric etch stop layer or lattice matched etch stop layer can have a predetermined uniform thickness thereby allowing the total height of the silicon substrate to be smaller. This, in turn, provides advantages to metal via like structures (e.g., a shorter metal via results in an improved aspect ratio).

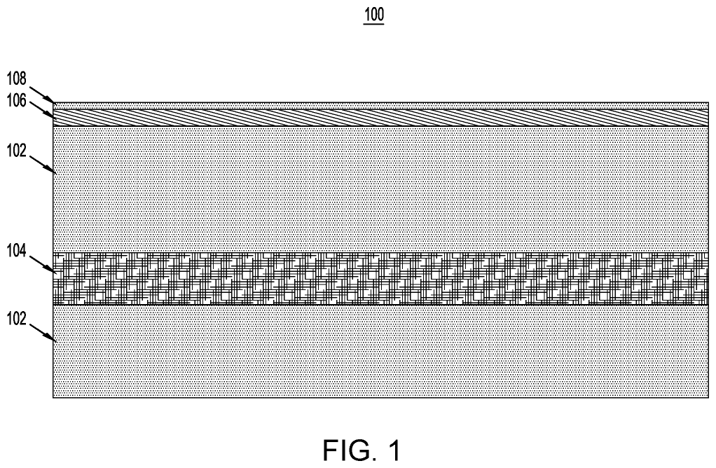

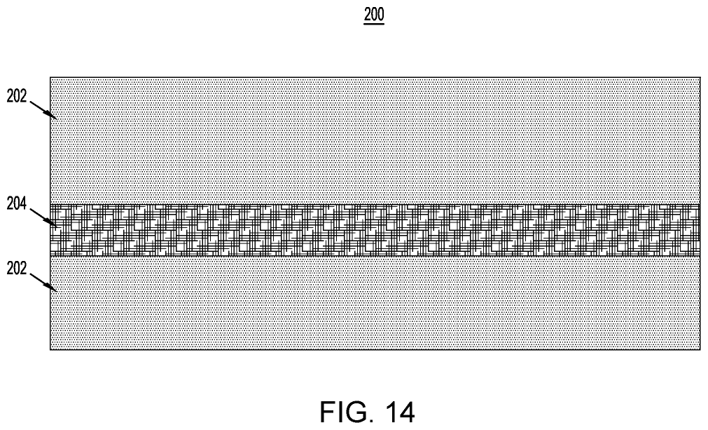

Referring now to the drawings in which like numerals represent the same of similar elements, FIGS. 1-27 illustrate various processes for fabricating a semiconductor structure. Note that the same reference numeral (100) is used to denote the semiconductor structure through the various intermediate fabrication stages illustrated in FIGS. 1-13, and the same reference numeral (200) is used to denote the semiconductor structure through the various intermediate fabrication stages illustrated in FIGS. 14-27. Note also that the semiconductor structure described herein can also be considered to be a semiconductor device and/or an integrated circuit, or some part thereof. For the purpose of clarity, some fabrication steps leading up to the production of the semiconductor structures as illustrated in FIGS. 1-27 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIGS. 1-13 show a semiconductor structure 100 in accordance with an illustrative embodiment. Referring now to FIG. 1, the semiconductor structure 100 is shown during an intermediate step of a method of fabricating a nanosheet transistor structure according to an embodiment of the invention. The semiconductor structure 100 includes a substrate 102 and an etch stop layer 104 formed in the substrate 102. The substrate 102 may be formed of any suitable semiconductor material, including various silicon-containing materials including but not limited to silicon (Si), silicon germanium (SiGe), and multi-layers thereof. Although silicon is the predominantly used semiconductor material in wafer fabrication, alternative semiconductor materials can be employed as additional layers, such as, but not limited to, SiGe, germanium (Ge), gallium arsenide (GaAs), gallium indium arsenide (InGaAs), cadmium telluride (CdTe), zinc selenide (ZnSe), etc. In one illustrative embodiment, the substrate 102 is silicon.

In various embodiments, the etch stop layer 104 is a layer of an etch stop material. For example, the etch stop layer 104 can be a layer of a buried oxide (BOX) in an SOI wafer, a layer of epitaxial silicon germanium (SiGe), a layer of epitaxial phosphorus doped silicon (Si:P) or any other material used as an etch stop in semiconductor device formation such as a rare earth oxide. In an illustrative embodiment, the etch stop layer 104 can have a thickness ranging from about 10 nanometers (nm) to about 200 nm. In one embodiment, the etch stop layer 104 has a different etch rate than the substrate 102.

Semiconductor structure 100 further includes a dielectric etch stop layer 106 disposed on the substrate 102. The dielectric etch stop layer 106 is a dielectric layer of an etch stop material. In some embodiments, the dielectric etch stop layer 106 is a buried oxide layer. In some embodiment, the dielectric etch stop layer 106 is a layer of epitaxial phosphorus doped silicon (Si:P). In some embodiments, the dielectric etch stop layer 106 is an epitaxial oxide layer. In some embodiments, the dielectric etch stop layer 106 is a lattice matched etch stop layer. In a non-limiting illustrative embodiment, the lattice matched etch stop layer is lattice matched to the substrate 102. The term “lattice matched” as used herein shall be understood to mean that the lattice constant of the lattice matched etch stop layer material discussed below can be varied arbitrarily so that it is equal to, or an integral multiple of the lattice constant of the silicon substrate. In illustrative embodiments, the lattice matched etch stop layer may comprise a rare earth material or a mixed rare earth material such as a mixed rare earth oxide. The rare earth oxide is any one of oxides of rare earth elements like cerium (Ce), yttrium (Y), Lathanium (La), Gadolinium (Ga), etc., and may be an oxide of one kind of rare earth elements, or two or more kinds of rare earth elements. When the rare earth oxide is expressed as ReO_{z} (where Re is one or more rare earth elements), 0<z≤3 is normally satisfied. Although the rare earth oxide is a cubic system or a tetragonal system, the cubic or tetragonal system includes those slightly distorted within a range which can be regarded as the cubic or tetragonal system substantially. The rare earth oxide typically takes a fluorite structure (CeO₂ structure) or a C-rare-earth structure (Y₂O₃ structure; bixbyite structure).

In addition, the mixed rare earth oxide is lattice-matched to the substrate 102. For example, in one embodiment, the lattice matched etch stop layer may comprise a mixed rare earth oxide on silicon, with the mixed rare earth oxide being single crystal and lattice-matched to silicon. In one illustrative embodiment, a mixed rare earth oxide is a metastable (Laₓ Y₁₋ₓ)₂O₃ alloy, where x is 0.33, a range of from 0.32 to 0.34 is less preferred. This alloy, at x is 0.33, can be lattice-matched to silicon and will crystallize in the cubic structure. That is, in its most basic form, the mixed rare earth oxide is grown on a silicon substrate.

In illustrative embodiments, a lattice constant of the mixed rare earth oxide may be twice a lattice constant of the substrate 102 (e.g., a silicon substrate). In illustrative embodiments, a mixed rare earth material includes oxides which can be used herein in terms of looking at the lattice constants and matching them so that they could match silicon. Suitable mixed rare earth oxides besides the (Laₓ Y₁₋ₓ)₂O₃ alloy include, for example, samarium (e.g., (Smₓ Y₁₋ₓ)₂O₃), cerium (Ceₓ Y₁₋ₓ)₂O₃), gadolinium (LaₓGd₁₋ₓ)₂O₃), gadolinium oxide and europium oxide (e.g., (GdₓEu₁₋ₓ)₂O₃), etc.

In illustrative embodiments, the mixed rare earth oxide comprises a ternary mixed rare earth oxide. In illustrative embodiments, the mixed rare earth oxide comprises a rare earth cubic ternary oxide. In illustrative embodiments, the mixed rare earth oxide will have a majority amount of one rare earth oxide compound, which is cubic, to ensure the resulting ternary mixed rare earth oxide formed on the silicon substrate has a cubic lattice, and will also have a minority amount of another rare earth oxide. A majority amount as used herein should be understood to mean at least about 55% of the ternary mixed rare earth oxide compound. A minority amount as used herein should be understood to mean no more than about 45% of the ternary mixed rare earth oxide compound. Examples of the majority compounds include, but are not limited to, Eu₂O₃, Gd₂O₃, Tb₂O₃, Dy₂O₃, Ho₂O₃, Er₂O₃, Tm₂O₃, Yb₂O₃, Lu₂O₃, Y₂O₃, etc. Examples of the minority compounds include, but are not limited to, La₂O₃, Ce₂O₃, Pr₂O₃₋, Nd₂O₃, Pm₂O₃₋, Sm₂O₃, etc.

To be lattice matched with the substrate 102, the ternary mixed rare earth oxide should have a substantially exact percentage of each compound. By substantially exact percentage of each compound means an exact percentage plus or minus one percent. Representative examples of rare earth oxides matching silicon include La—Y—O with 33% lanthanum, 68.8% gadolinium oxide with 31.2% europium oxide, 91.3% gadolinium oxide with 8.7% lanthanum oxide, 58.5% erbium oxide with 41.2% neodymium oxide, 62.6% erbium oxide with 37.4% lanthanum oxide, etc.

The lattice matched etch stop layer can be formed using conventional epitaxial growth techniques such as molecular beam epitaxy (MBE), so that an epitaxial film of good quality may be grown on substrate 102 by depositing the mixed rare earth material such as (Laₓ Y₁₋ₓ)₂O₃. In some embodiments, the dielectric etch stop layer 106 is a lattice matched epitaxial oxide etch stop layer.

In an illustrative embodiment, the dielectric etch stop layer 106 can have a thickness ranging from about 2 nm to about 20 nm. In one embodiment, the dielectric etch stop layer 106 has a different etch rate than the substrate 102.

Semiconductor structure 100 further includes a semiconductor layer 108 on the dielectric etch stop layer 106. In some embodiments, the semiconductor layer 108 is composed of silicon. The semiconductor layer 108 is relatively thin and can have a thickness ranging from about 5 nm to about 100 nm. In some embodiments, the semiconductor layer 108 can have a thickness ranging from about 10 nm to about 25 nm.

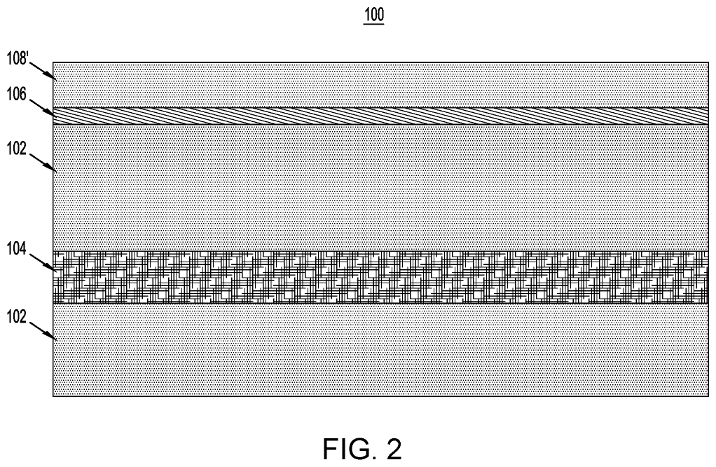

Referring now to FIG. 2, the semiconductor structure 100 is shown following growing a semiconductor material on the semiconductor layer 108 according to an embodiment of the invention. The semiconductor material such as silicon is grown on the semiconductor layer 108 to form a semiconductor layer 108′ of a desired sub-fin thickness. In an illustrative embodiment, the semiconductor material such as silicon can be grown on the semiconductor layer 108 using conventional epitaxial growth techniques such as low-pressure chemical vapor deposition (LPCVD), so that an epitaxial film of good quality may be grown. By epitaxially growing the semiconductor layer 108′, the semiconductor layer 108′ can have its natural lattice constant and be defect free or free of crystalline defects.

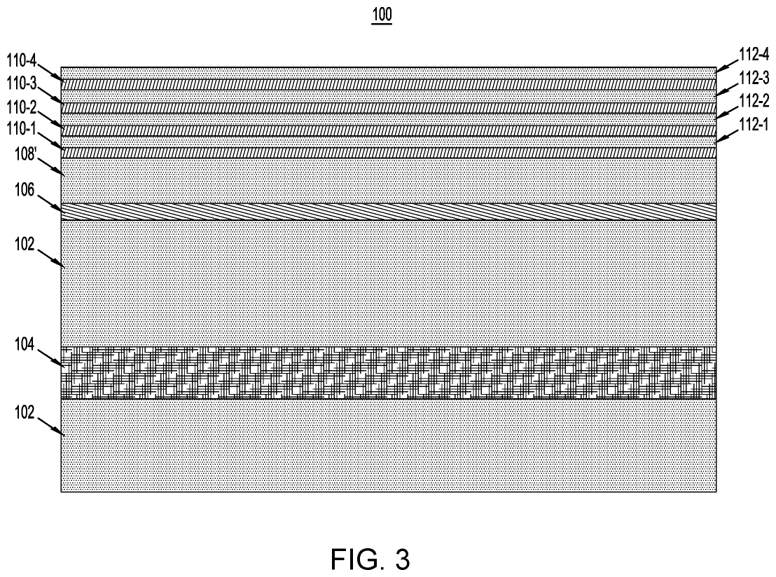

Referring now to FIG. 3, the semiconductor structure 100 is shown following the formation of nanosheets over the semiconductor layer 108′ according to an embodiment of the invention. The nanosheets include sacrificial layers 110-1, 110-2, 1160-3 and 110-4 (collectively, the sacrificial layers 110), and nanosheet channel layers 112-1, 112-2, 112-3 and 112-4 (collectively, the nanosheet channel layers 112).

The sacrificial layers 110 are illustratively formed of a sacrificial material, such that they may be etched or otherwise removed selectively. In some embodiments, the sacrificial layers 110 are formed of Silicon-Germanium alloy (SiGe). For example, the sacrificial layers 110 may have a relatively lower percentage of Ge (e.g., 25% Ge).

The nanosheet channel layers 112 may be formed of Si or another suitable material (e.g., a material similar to that used for the substrate 102).

Although four layers each of the sacrificial layers 110 and the nanosheet channel layers 112 are shown, the number of the sacrificial layers 110 and the nanosheet channel layers 112 should not be considered limiting and any number are contemplated.

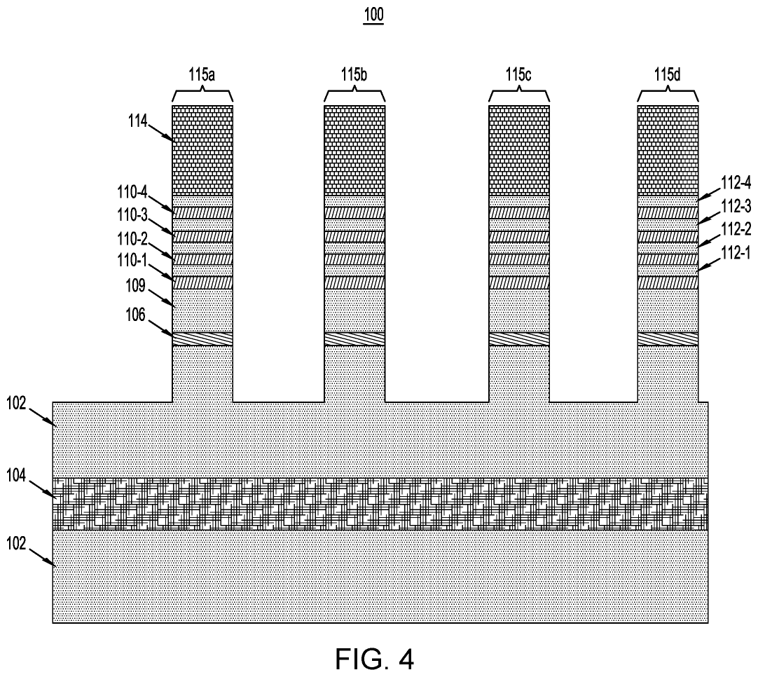

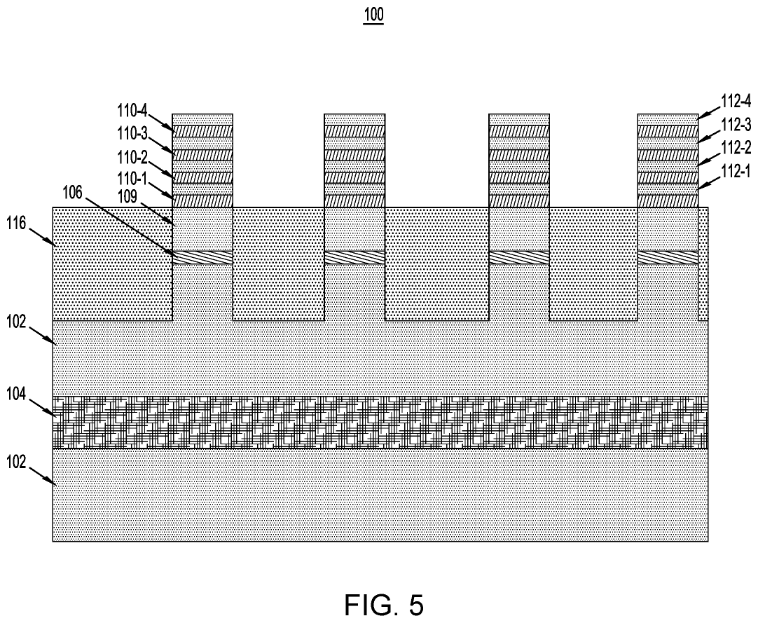

Referring now to FIGS. 4 and 5, the semiconductor structure 100 is shown following nanosheet patterning and formation of FET stacks 115a, 115b, 115c and 115d between adjacent shallow trench isolation (STI) regions 116 according to an embodiment of the invention. Each of the FET stacks 115a, 115b, 115c and 115d can contain a respective FET device. However, this is merely illustrative and it is contemplated that the FET stacks 115a, 115b, 115c and 115d can contain any number of FET devices. The FET stacks 115a, 115b, 115c and 115d may comprise nFET devices or pFET devices or combinations thereof. In addition, nanosheet patterning and formation of the FET stacks 115a, 115b, 115c and 115d also transforms the semiconductor layer 108′ into semiconductor fins 109 under the sacrificial layers 110 and the nanosheet channel layers 112. In illustrative embodiments, the semiconductor fins 109 are of a uniform height. For example, the semiconductor fins 109 can have a height ranging from about 5 to about 50 nm. In illustrative embodiments, the dielectric etch stop layer 106 and the respective semiconductor fin of the semiconductor fins 109 are of the same width.

The FET stacks 115a, 115b, 115c and 115d may be formed by patterning a hardmask layer 114 over the semiconductor structure 100, followed by etching exposed portions of the nanosheet channel layers 112, the sacrificial layers 110, and through a portion of the substrate 102. The hardmask layer 114 can be composed of, for example, SiN. The STI regions 116 may be formed of a dielectric material such as silicon dioxide (SiO₂), silicon oxycarbide (SiOC), silicon oxynitride (SiON), etc. After the STI regions 116 are formed, the hardmask layer 114 is removed using conventional etching techniques such as a wet etch.

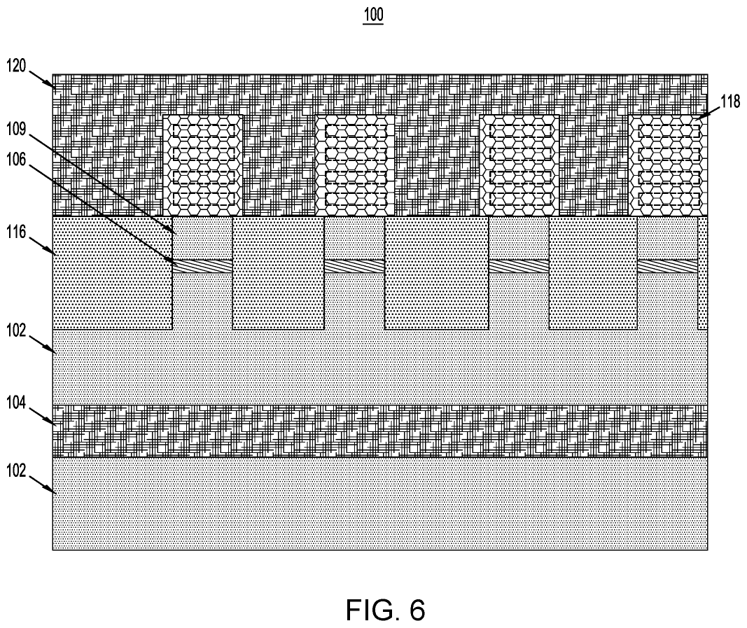

Referring now to FIG. 6, the semiconductor structure 100 is shown following various FEOL processing steps according to an embodiment of the invention. The various FEOL processing steps, which are not detailed in the present context, are carried out to form a FEOL structure that includes source/drain regions 118 and an interlevel dielectric (ILD) layer 120 following removal of the sacrificial layers 110. In illustrative embodiments, the source/drain regions 118 may be formed next to and contacting the nanosheet channel layers 112 using epitaxial growth processes. The source/drain regions 118 may be suitably doped, such as using in-situ doping during epitaxial formation. N-type dopants may be selected from a group of phosphorus (P), arsenic (As) and antimony (Sb), and p-type dopants may be selected from a group of boron (B), and gallium (Ga), In some embodiments, the epitaxy process comprises in-situ doping (dopants are incorporated in epitaxy material during epitaxy).

Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 2×10²⁰ cm⁻³ to 3×10²¹ cm⁻³, or preferably between 8×10²⁰ cm⁻³ to 2×10²¹ cm⁻³.

The ILD layer 120 is formed on the source/drain regions 118 and over the top of the STI regions 116 by conventional deposition processes such as PVD, ALD, CVD. The ILD layer 120 may be formed of any suitable isolating material, such as SiO₂, SiOC, SiON, etc.

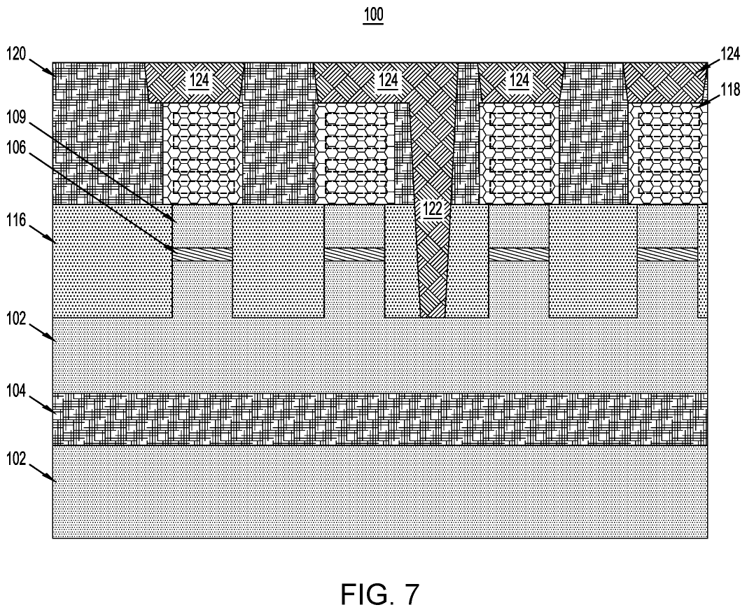

Referring now to FIG. 7, the semiconductor structure 100 is shown following the formation of a metal via 122 and middle-of-the-line (MOL) contacts 124 in the ILD layer 120 according to an embodiment of the invention. For example, a masking layer (not shown) can be deposited on the ILD layer 120 using any conventional deposition process such as PVD, ALD and CVD. Next, the masking layer is patterned and then selectively etched to form a via opening and middle-of-the-line contact openings. Next a conductive metal is deposited in the via opening and middle-of-the-line contact openings to form the metal via 122 and the middle-of-the-line contacts 124 by conventional deposition processes such as PVD, ALD, CVD, and/or plating. The conductive metal can be any suitable conductive material such as, for example, tungsten (W), aluminum (Al), copper (Cu), cobalt (Co), nickel (Ni), titanium (Ti), ruthenium (Ru), molybdenum (Mo), or any other suitable conductive material.

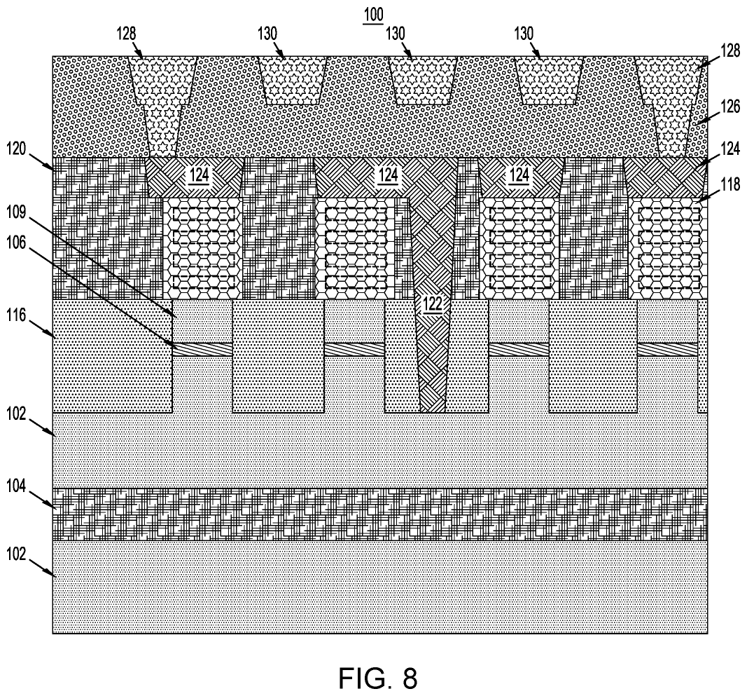

Referring now to FIG. 8, the semiconductor structure 100 is shown following formation of an ILD layer 126, followed by patterning and etching vias in the exposed ILD layer 126 according to an embodiment of the invention. The ILD layer 126 is first deposited on semiconductor structure 100 by similar processes and similar material as the ILD layer 120. Next, the ILD layer 126 is subjected to patterning and etching vias in the exposed ILD layer 126. A suitable conductive metal is then deposited in the vias to form conductive lines 128 and metal vias 130. The conductive metal can be any conductive metal as discussed above. The conductive lines 128 can be a power line connected to the semiconductor structure 100 through the metal vias 130 and the middle-of-the-line contacts 124.

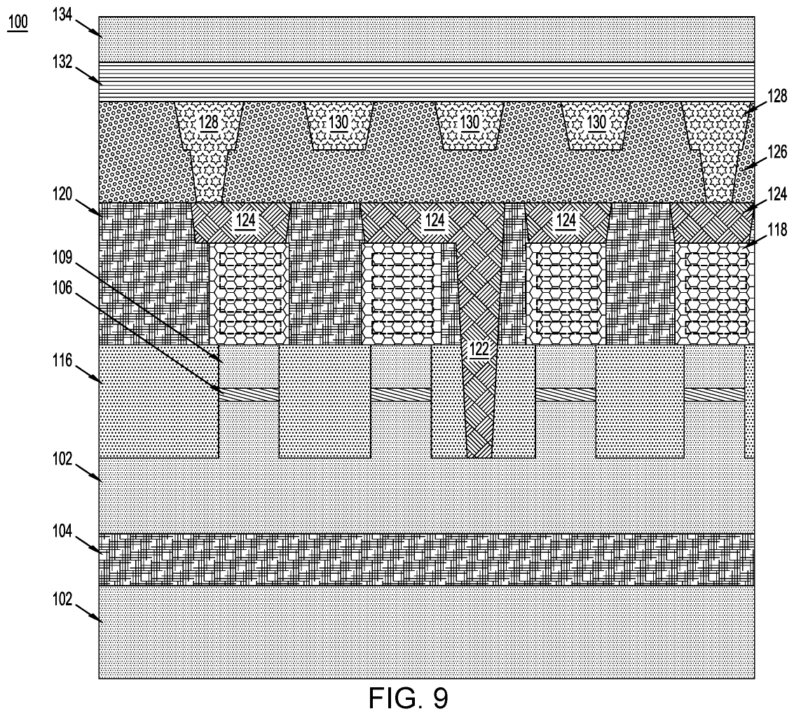

Referring now to FIG. 9, the semiconductor structure 100 is shown following formation of a frontside back-end-of-line (BEOL) interconnect 132 and a carrier wafer 134 according to an embodiment of the invention. The frontside BEOL interconnect 132 is formed on the semiconductor structure 100 followed by bonding of the structure (e.g., the frontside BEOL interconnect 132) to the carrier wafer 134. The frontside BEOL interconnect 132 includes various BEOL interconnect structures. For example, the frontside BEOL interconnect 132 is a metallization structure that includes one or more metal layers disposed on a side of the semiconductor structure 100 opposite of the side on which the backside BEOL metallization structure is disposed. The metal layers of the frontside BEOL interconnect 132 each have metal lines for making interconnections to the semiconductor device.

The carrier wafer 134 may be formed of materials similar to that of the substrate 102, and may be formed over the frontside BEOL interconnect 132 using a wafer bonding process, such as dielectric-to-dielectric bonding.

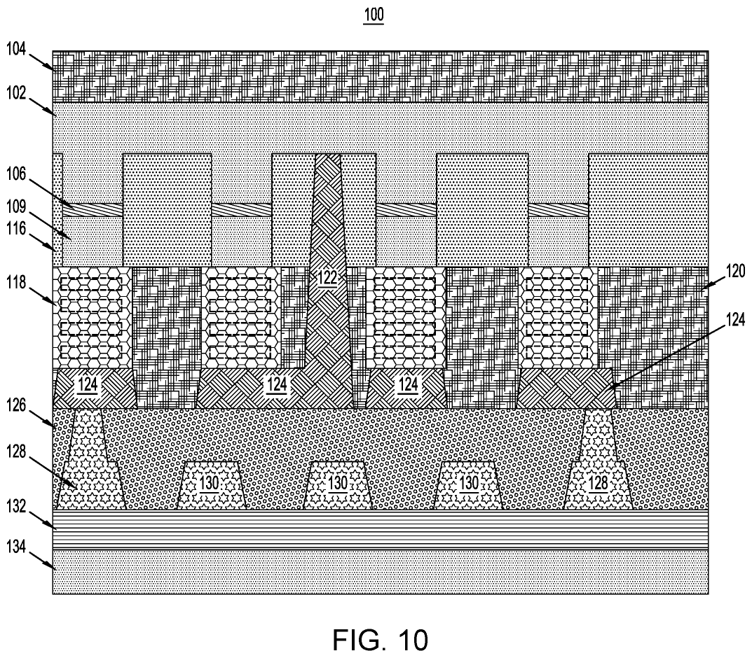

Referring now to FIG. 10, the semiconductor structure 100 is shown following backside processing according to an embodiment of the invention. The backside processing includes using the carrier wafer 134 such that the structure is “flipped” over so that the backside of the substrate 102 (i.e., the back surface) is facing up for backside processing as shown. Next, portions of the substrate 102 may be removed from the backside using, for example, grinding followed by a wet etch to selectively remove the substrate 102 until the etch stop layer 104 is reached.

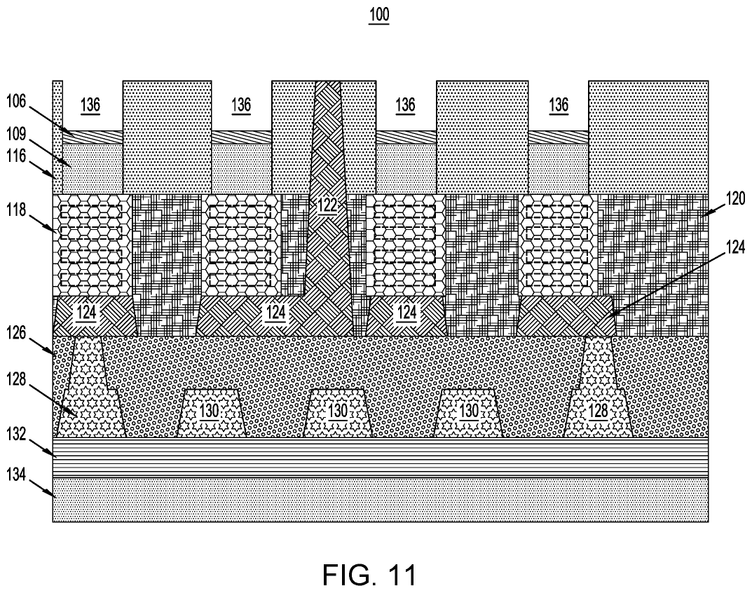

Referring now to FIG. 11, the semiconductor structure 100 is shown following the removal of the etch stop layer 104 according to an embodiment of the invention. The etch stop layer 104 is selectively removed using, for example, a wet etch to selectively remove etch stop layer 104 until the substrate 102 is reached. The remaining portions of the substrate 102 are removed to expose the dielectric etch stop layer 106 on a backside of the semiconductor fins 109 thereby forming openings 136. The remaining portions of the substrate 102 are removed utilizing a selective etch process such as a wet etch.

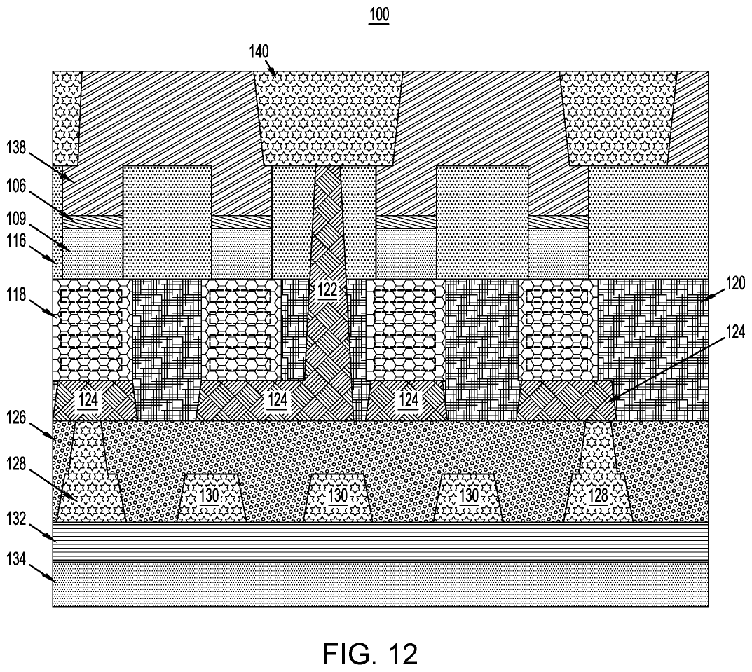

Referring now to FIG. 12, the semiconductor structure 100 is shown following formation of a backside ILD layer 138 and backside power rails 140 according to an embodiment of the invention. The backside ILD layer 138 may be formed by similar processes and similar material as the ILD layer 120. The material of the backside ILD layer 138 may initially be overfilled, followed by planarization (e.g., using CMP). Next, the backside power rails 140 are formed in the backside ILD layer 138 by first patterning and etching vias in the exposed backside ILD layer 138. A conductive metal is then deposited in the vias and on top of the backside ILD layer 138, followed by CMP to remove any metal on top of the backside ILD layer 138. A suitable conductive metal can be any of the metals discussed above.

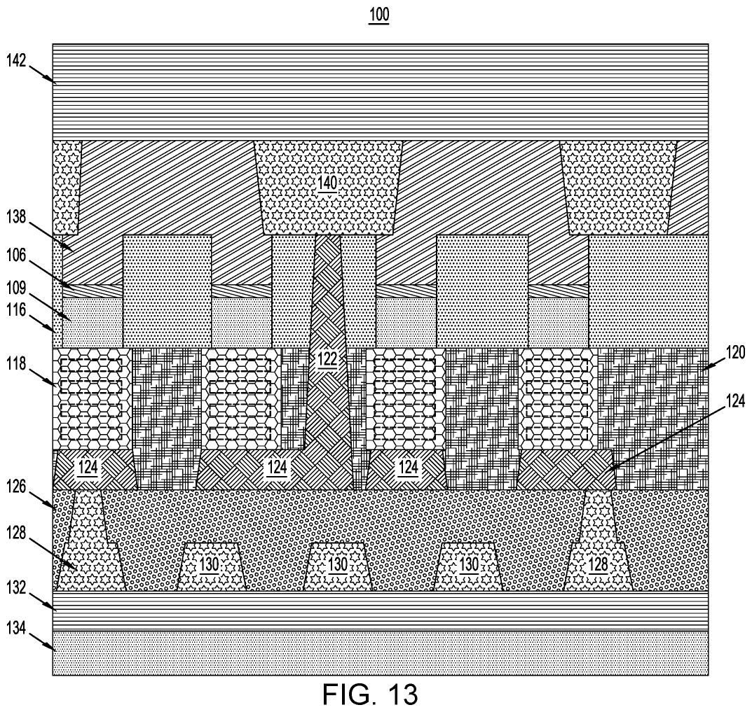

Referring now to FIG. 13, the semiconductor structure 100 is shown following the formation of a backside power delivery network 142 according to an embodiment of the invention. The backside power delivery network 142 is formed over the semiconductor structure 100 including the backside power rails 140 and is based on creation of a wiring scheme that is disposed on both sides of the device layer (front end of line structure). For example, the power signals can be routed through the backside power delivery network 142 composed of metal lines coupled to the semiconductor structure 100 to provide power to a number of semiconductor devices.

FIGS. 14-27 show a semiconductor structure 200 illustrating an alternative non-limiting illustrative embodiment. Referring now to FIG. 14, the semiconductor structure 200 is shown during an intermediate step of a method of fabricating a nanosheet transistor structure according to an embodiment of the invention. The semiconductor structure 200 includes a substrate 202 and an etch stop layer 204 formed in the substrate 202. The substrate 202 and the etch stop layer 204 may be formed of any suitable material as discussed above for the substrate 102 and the etch stop layer 104.

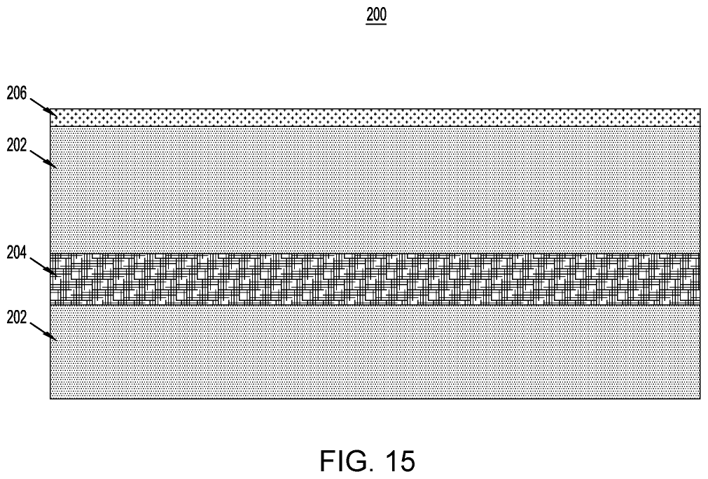

Referring now to FIG. 15, the semiconductor structure 200 is shown following the formation of a lattice matched etch stop layer 206 formed on the substrate 202 according to an embodiment of the invention. In a non-limiting illustrative embodiment, the lattice matched etch stop layer 206 is lattice matched to the substrate 202. The lattice matched etch stop layer 206 may be formed of any similar material and processes as discussed above such as, for example, a rare earth material or a mixed rare earth material such as a mixed rare earth oxide. The mixed rare earth oxide is lattice-matched to the substrate 202. For example, in one embodiment, the lattice matched etch stop layer 206 may comprise a mixed rare earth oxide on silicon, with the mixed rare earth oxide being single crystal and lattice-matched to silicon. In one illustrative embodiment, a mixed rare earth oxide is a metastable (Laₓ Y₁₋ₓ)₂O₃ alloy, where x is 0.33, a range of from 0.32 to 0.34 is less preferred. This alloy, at x is 0.33, can be lattice-matched to silicon and will crystallize in the cubic structure. That is, in its most basic form, the mixed rare earth oxide is grown on a silicon substrate.

In illustrative embodiments, a lattice constant of the mixed rare earth oxide may be twice a lattice constant of the substrate 202 (e.g., a silicon substrate). In illustrative embodiments, a mixed rare earth material includes oxides which can be used herein in terms of looking at the lattice constants and matching them so that they could match silicon. Suitable mixed rare earth oxides besides the (Laₓ Y₁₋ₓ)₂O₃ alloy include, for example, samarium (e.g., (Smₓ Y₁₋ₓ)₂O₃), cerium (Ceₓ Y₁₋ₓ)₂O₃), gadolinium (LaₓGd₁₋ₓ)₂O₃), gadolinium oxide and europium oxide (e.g., (GdₓEu₁₋ₓ)₂O₃), etc.

In illustrative embodiments, the mixed rare earth oxide comprises a ternary mixed rare earth oxide. In illustrative embodiments, the mixed rare earth oxide comprises a rare earth cubic ternary oxide. In illustrative embodiments, the mixed rare earth oxide will have a majority amount of one rare earth oxide compound, which is cubic, to ensure the resulting ternary mixed rare earth oxide formed on the silicon substrate has a cubic lattice, and will also have a minority amount of another rare earth oxide. A majority amount as used herein should be understood to mean at least about 55% of the ternary mixed rare earth oxide compound. A minority amount as used herein should be understood to mean no more than about 45% of the ternary mixed rare earth oxide compound. Examples of the majority compounds include, but are not limited to, Eu₂O₃, Gd₂O₃, Tb₂O₃, Dy₂O₃, Ho₂O₃, Er₂O₃, Tm₂O₃, Yb₂O₃, Lu₂O₃, Y₂O₃, etc. Examples of the minority compounds include, but are not limited to, La₂O₃₋, Ce₂O₃, Pr₂O₃₋, Nd₂O₃, Pm₂O₃₋, Sm₂O₃, etc.

To be lattice matched with the substrate 202, the ternary mixed rare earth oxide should have a substantially exact percentage of each compound. By substantially exact percentage of each compound means an exact percentage plus or minus one percent. Representative examples of rare earth oxides matching silicon include La—Y—O with 33% lanthanum, 68.8% gadolinium oxide with 31.2% europium oxide, 91.3% gadolinium oxide with 8.7% lanthanum oxide, 58.5% erbium oxide with 41.2% neodymium oxide, 62.6% erbium oxide with 37.4% lanthanum oxide, etc.

In an illustrative embodiment, the lattice matched etch stop layer 206 can have a thickness ranging from about 10 nm to about 200 nm.

In one embodiment, the lattice matched etch stop layer 206 has a different etch rate than the substrate 202.

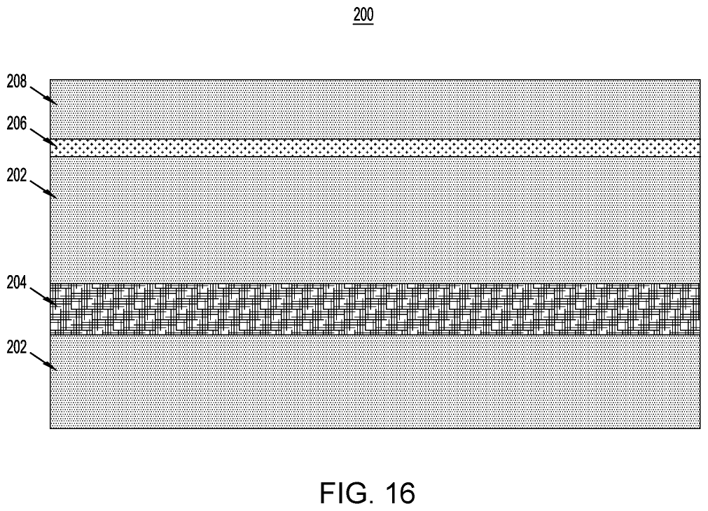

Referring now to FIG. 16, the semiconductor structure 200 is shown following growing a semiconductor material on the lattice matched etch stop layer 206 according to an embodiment of the invention. The semiconductor material is grown on the lattice matched etch stop layer 206 to form a semiconductor layer 208 utilizing standard growth processing such as epitaxial growth processing. Following the growth of the semiconductor layer 208, any overgrown material can be removed by a standard planarization process such as CMP or any other suitable planarization process. In an illustrative embodiment, silicon can be grown on the lattice matched etch stop layer 206 using conventional epitaxial growth techniques such as MBE, so that an epitaxial film of good quality may be grown. In some embodiments the semiconductor material is lattice matched to the lattice matched etch stop layer 206 and the substrate 202. By epitaxially growing the semiconductor layer 208 on the lattice matched etch stop layer 206 that is lattice matched to the substrate 202, the newly grown semiconductor layer 208 can have its natural lattice constant and be defect free or free of crystalline defects. In an illustrative embodiment, the semiconductor layer 208 can have a thickness ranging from about 5 nm to about 100 nm. In some embodiments, the semiconductor layer 208 can have a thickness ranging from about 10 nm to about 25 nm.

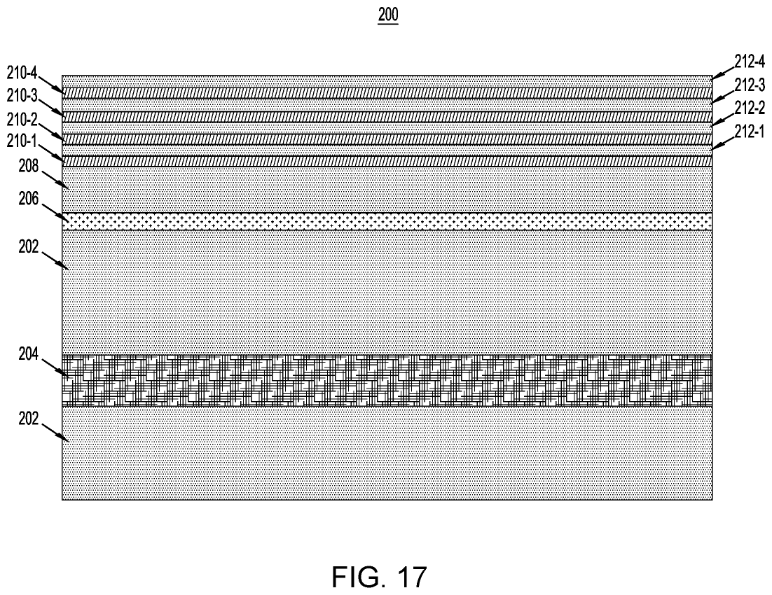

Referring now to FIG. 17, the semiconductor structure 200 is shown following formation of nanosheets over the semiconductor layer 208 according to an embodiment of the invention. The nanosheets include sacrificial layers 210-1, 210-2, 210-3 and 210-4 (collectively, the sacrificial layers 210), and nanosheet channel layers 212-1, 212-2, 212-3 and 212-4 (collectively, the nanosheet channel layers 212).

The sacrificial layers 210 are illustratively formed of a sacrificial material, such that they may be etched or otherwise removed selectively. In some embodiments, the sacrificial layers 210 are formed of SiGe. For example, the sacrificial layers 210 may have a relatively lower percentage of Ge (e.g., 25% Ge).

The nanosheet channel layers 212 may be formed of Si or another suitable material (e.g., a material similar to that used for the substrate 202).

Although four layers each of the sacrificial layers 210 and the nanosheet channel layers 212 are shown, the number of the sacrificial layers 210 and the nanosheet channel layers 212 should not be considered limiting and any number are contemplated.

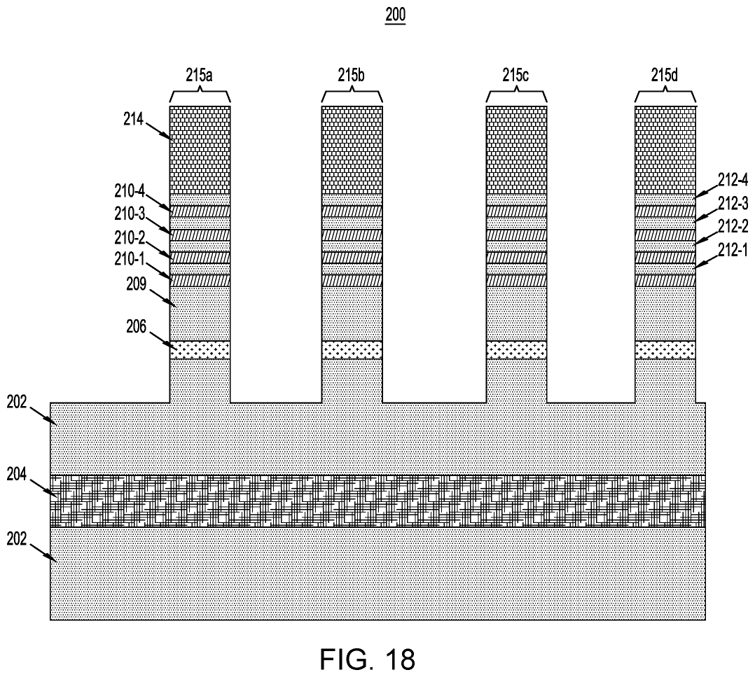

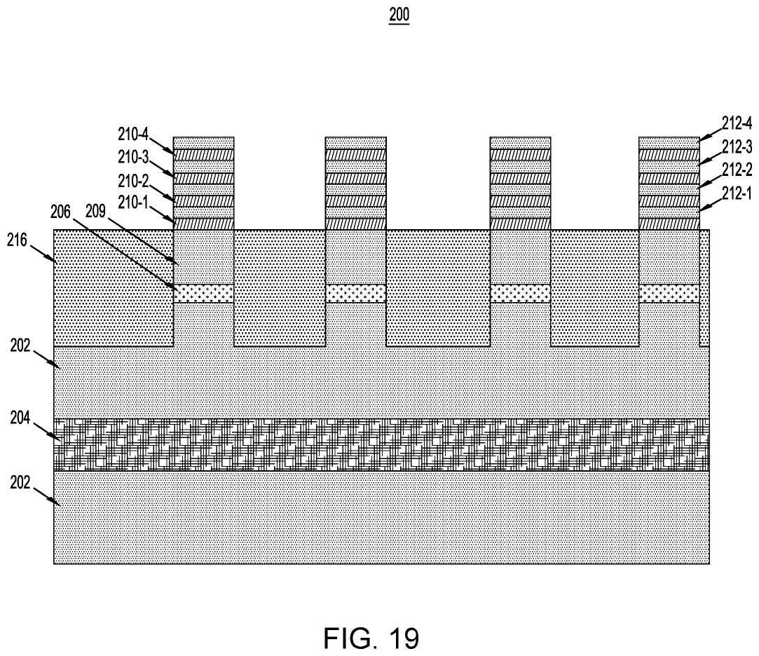

Referring now to FIGS. 18 and 19, the semiconductor structure 200 is shown following nanosheet patterning and formation of FET stacks 215a, 215b, 215c and 215d between adjacent STI regions 216 according to an embodiment of the invention. Each of the FET stacks 215a, 215b, 215c and 215d can contain a respective FET device. However, this is merely illustrative and it is contemplated that the FET stacks 215a, 215b, 215c and 215d can contain any number of FET devices. The FET stacks 215a, 215b, 215c and 215d may comprise nFET devices or pFET devices or combinations thereof. In addition, nanosheet patterning and formation of the FET stacks 215a, 215b, 215c and 215d also transforms the semiconductor layer 208 into semiconductor fins 209 under the sacrificial layers 210 and the nanosheet channel layers 212. In illustrative embodiments, the semiconductor fins 209 are of a uniform height. For example, the semiconductor fins 209 can have a height ranging from about 5 to about 50 nm. In illustrative embodiments, the lattice matched etch stop layer 206 and the respective fin of the semiconductor fins 209 are of the same width.

FET stacks 215a, 215b, 215c and 215d are formed by patterning a hardmask layer 214 over the semiconductor structure 200, followed by etching exposed portions of the nanosheet channel layers 212, the sacrificial layers 210, and through a portion of the substrate 202. The hardmask layer 214 may be formed of similar material as the hardmask layer 114. The STI regions 216 may be formed of similar material as STI regions 116. After the STI regions 216 are formed, the hardmask layer 214 is removed using conventional etching techniques such as a wet etch.

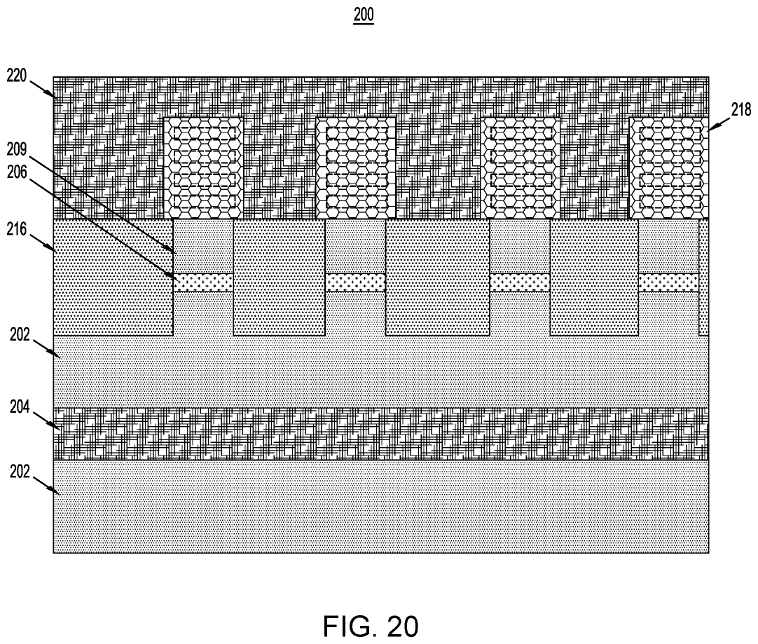

Referring now to FIG. 20, the semiconductor structure 200 is shown after various FEOL processing steps according to an embodiment of the invention. The FEOL processing steps, which are not detailed in the present context, are carried out to form a FEOL structure that includes source/drain regions 218 and an ILD layer 220 following removal of the sacrificial layers 210. In illustrative embodiments, the source/drain regions 218 may be formed over the nanosheet channel layers 212 using similar epitaxial growth processes and materials as the source/drain regions 118.

The ILD layer 220 is formed on the source/drain regions 218 and over the top of the STI regions 216 by similar processes and similar materials as the ILD layer 120.

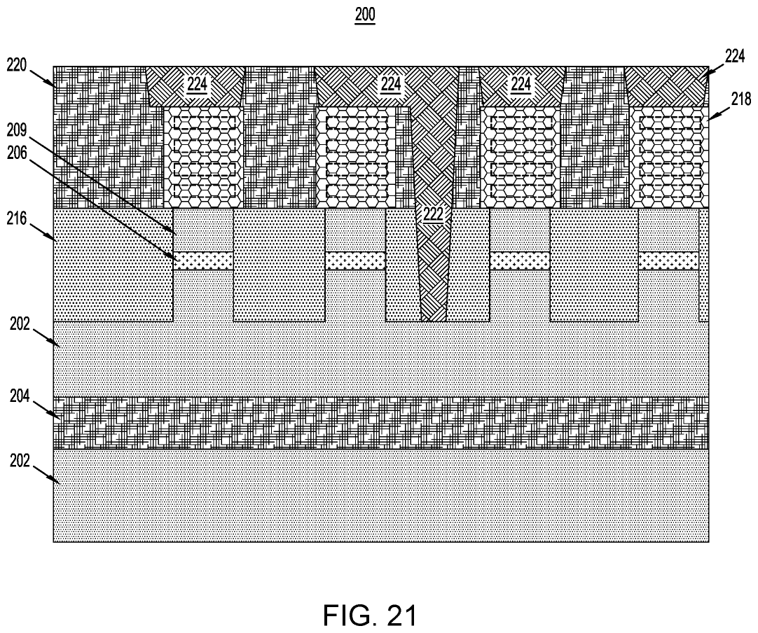

Referring now to FIG. 21, the semiconductor structure 200 is shown following the formation of a metal via 222 and middle-of-the-line (MOL) contacts 224 in ILD layer 220 according to an embodiment of the invention. For example, the metal via 222 and the MOL contacts 224 can be formed by similar processes and similar conductive metals as the metal via 122 and the middle-of-the-line contacts 124.

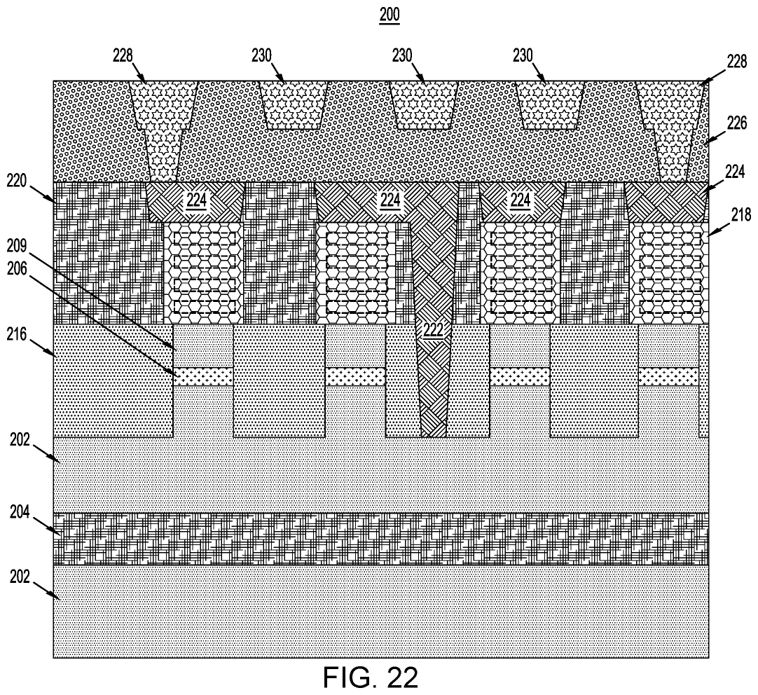

Referring now to FIG. 22, the semiconductor structure 200 is shown following the formation of an ILD layer 226 according to an embodiment of the invention. The ILD layer 226 is first deposited on the semiconductor structure 200, followed by patterning and etching vias in the exposed ILD layer 226. The ILD layer 226 can be formed by similar processes and similar material as the ILD layer 120. A suitable conductive metal is then deposited in the vias to form conductive lines 228 and metal vias 230. The conductive metal can be any conductive metal as discussed above. The conductive lines 228 can be a power line connected to the semiconductor structure 200 through the metal vias 230 and the MOL contacts 224.

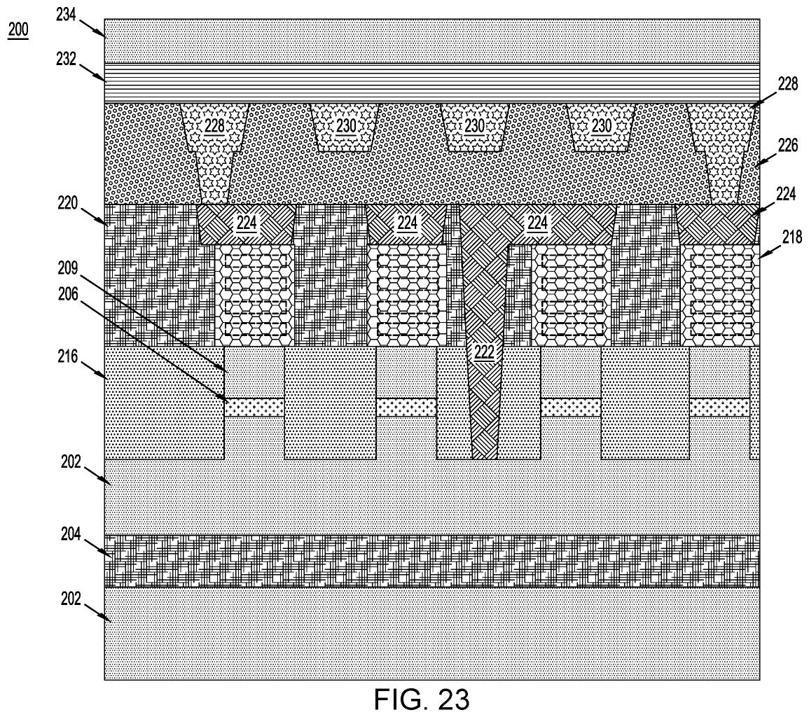

Referring now to FIG. 23, the semiconductor structure 200 is shown following the formation of a frontside back-end-of-line (BEOL) interconnect 232 and a carrier wafer 234 according to an embodiment of the invention. The frontside BEOL interconnect 232 is first formed followed by bonding of the structure (e.g., the frontside BEOL interconnect 232) to the carrier wafer 234. The frontside BEOL interconnect 232 includes various BEOL interconnect structures. For example, the frontside BEOL interconnect 232 is a metallization structure that includes one or more metal layers disposed on a side of the semiconductor structure 200 opposite of the side on which the backside BEOL metallization structure is disposed. The metal layers of the frontside BEOL interconnect 232 each have metal lines for making interconnections to the semiconductor device.

The carrier wafer 234 may be formed of materials similar to that of the substrate 202, and may be formed over the frontside BEOL interconnect 232 using a wafer bonding process, such as dielectric-to-dielectric bonding.

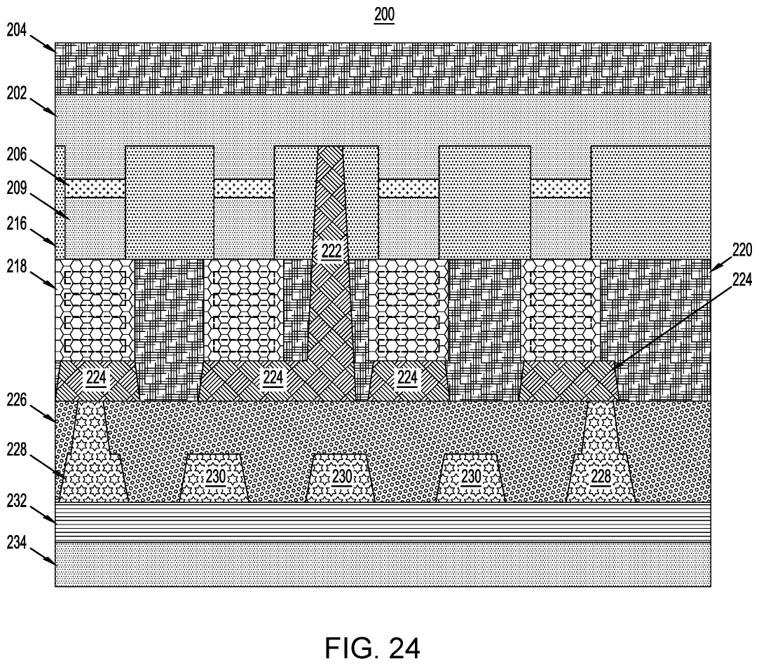

Referring now to FIG. 24, the semiconductor structure 200 is shown following backside processing according to an embodiment of the invention. The backside process is carried out using the carrier wafer 234 such that the structure is “flipped” over so that the backside of the substrate 202 (i.e., the back surface) is facing up for backside processing as shown. Next, portions of the substrate 202 may be removed from the backside using, for example, a wet etch to selectively remove the substrate 202 until the etch stop layer 204 is reached.

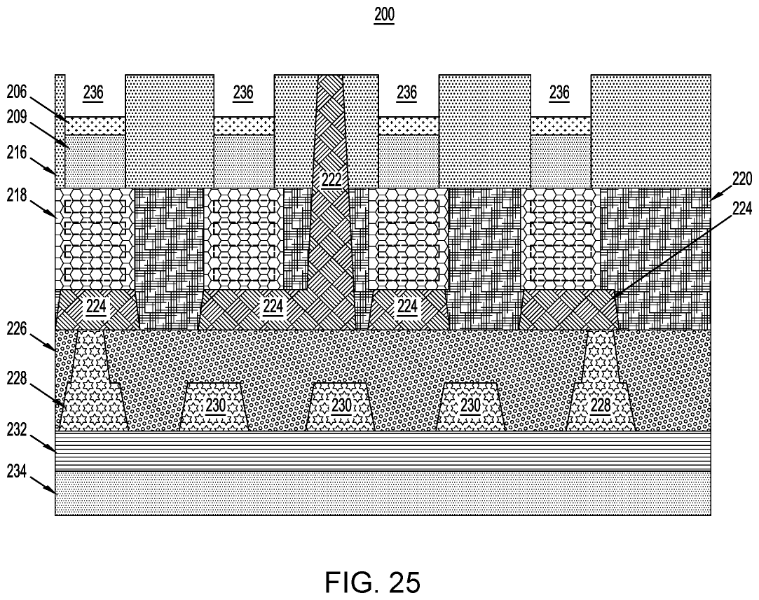

Referring now to FIG. 25, the semiconductor structure 200 is shown following the removal of the etch stop layer 204 according to an embodiment of the invention. The etch stop layer 204 is selectively removed using, for example, a wet etch to selectively remove the etch stop layer 204 until the substrate 202 is reached. The remaining portions of the substrate 202 are removed to expose the lattice matched etch stop layer 206 on a backside of the semiconductor fins 209 thereby forming openings 236. The remaining portions of the substrate 202 are removed utilizing a selective etch process such as a wet etch.

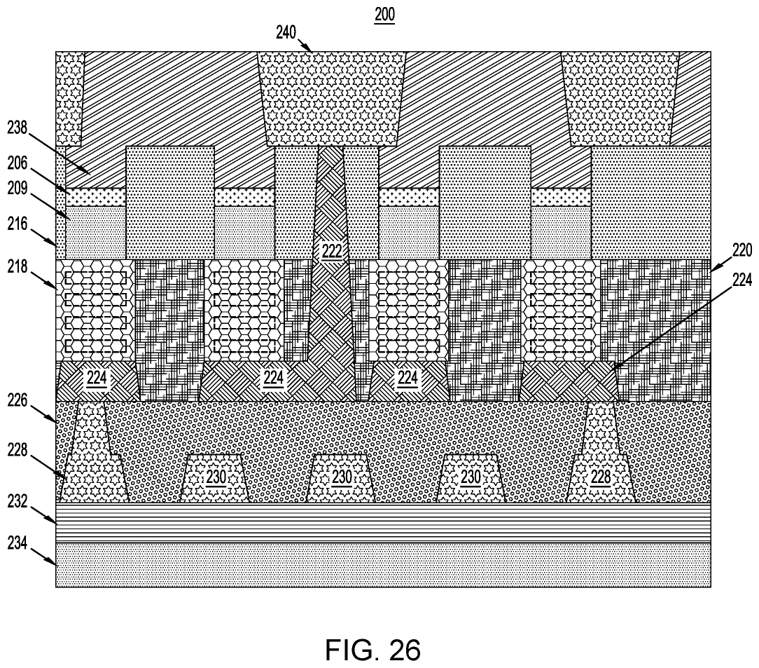

Referring now to FIG. 26, the semiconductor structure 200 is shown following the formation of a backside ILD layer 238 according to an embodiment of the invention. The backside ILD layer 238 may be formed of similar processes and similar material as the ILD layer 120. The material of the backside ILD layer 238 may initially be overfilled, followed by planarization (e.g., using CMP). Next, backside power rails 240 are formed in the backside ILD layer 238 by first patterning and etching vias in the exposed backside ILD layer 238. A suitable conductive metal is then deposited in the vias and on top of the backside ILD layer 238, followed by CMP to remove any metal on top of the backside ILD layer 238. A suitable conductive metal can be any of the metals discussed above.

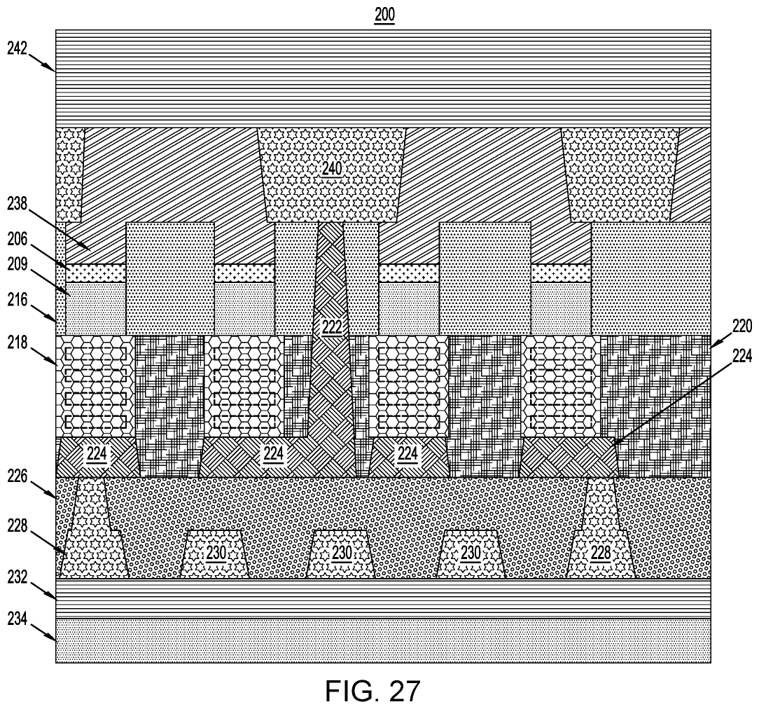

Referring now to FIG. 27, the semiconductor structure 200 is shown following the formation of a backside power delivery network 242 according to an embodiment of the invention. The backside power delivery network 242 is formed over the semiconductor structure 200 including the backside power rails 240 and is based on creation of a wiring scheme that is disposed on both sides of the device layer (front end of line structure). For example, the power signals can be routed through the backside power delivery network 242 composed of metal lines coupled to the semiconductor structure 200 to provide power to a number of semiconductor devices.

According to an aspect of the invention, a semiconductor structure comprises a first semiconductor fin disposed on a first source/drain region of a first nanosheet transistor device, a second semiconductor fin disposed on a second source/drain region of a second nanosheet transistor device, a first dielectric etch stop layer disposed on the first semiconductor fin, and a second dielectric etch stop layer disposed on the second semiconductor fin. The first semiconductor fin and the second semiconductor fin are of a uniform height.

In embodiments, the first semiconductor fin, the first semiconductor fin and the first dielectric etch stop layer have a same width, and the second semiconductor fin and the second dielectric etch stop layer have a same width.

In embodiments, the first dielectric etch stop layer and the second dielectric etch stop layer each comprises a buried oxide layer.

In embodiments, the first dielectric etch stop layer and the second dielectric etch stop layer each comprises an epitaxial oxide layer.

In embodiments, the first semiconductor fin and the second semiconductor fin comprise a first backside silicon fin and a second backside silicon fin.

In embodiments, the semiconductor structure further comprises a middle-of-the-line contact disposed on a given one of the first source/drain region and the second source/drain region, and a metal via connecting a backside power rail to the middle-of-the-line contact.

In embodiments, the semiconductor structure further comprises a backside power delivery network disposed over the backside power rail.

According to another aspect of the invention, a semiconductor structure comprises a first silicon fin disposed on a first source/drain region of a first nanosheet transistor device, a second silicon fin disposed on a second source/drain region of a second nanosheet transistor device, a first dielectric etch stop layer disposed on the first silicon fin, and a second dielectric etch stop layer disposed on the second silicon fin. The first silicon fin and the second silicon fin are disposed between adjacent shallow trench isolation regions. The first silicon fin and the second silicon fin are of a uniform height.

In embodiments, the first dielectric etch stop layer is a first lattice matched etch stop layer and the second dielectric etch stop layer is a second lattice matched etch stop layer.

In embodiments, the first silicon fin and the second silicon fin are each epitaxially grown on the first lattice matched etch stop layer and the second lattice matched etch stop layer.

In embodiments, the first lattice matched etch stop layer comprises a first epitaxial oxide layer and the second lattice matched etch stop layer comprises a second epitaxial oxide layer.

In embodiments, the first epitaxial oxide layer and the second epitaxial oxide layer each comprises a layer of a mixed rare earth oxide, the mixed rare earth oxide being single crystal and lattice-matched to the first silicon fin and the second silicon fin.

In embodiments, the mixed rare earth oxide comprises a compound having a chemical formula (AₓB₁₋ₓ)₂O₃, wherein A represents a first rare earth element and B represents a second rare earth element.

In embodiments, the mixed rare earth oxide comprises (Laₓ Y₁₋ₓ)₂O₃ and x is 0.33.

In embodiments, the first silicon fin and the second silicon fin comprise a first backside silicon fin and a second backside silicon fin.

In embodiments, the semiconductor structure further comprises a middle-of-the-line contact disposed on a given one of the first source/drain region and the second source/drain region, and a metal via connecting a backside power rail to the middle-of-the-line contact.

In embodiments, the semiconductor structure further comprises a backside power delivery network disposed over the backside power rail.

According to yet another aspect of the invention, integrated circuit comprises one or more semiconductor structures, wherein at least one of the one or more semiconductor structures comprises a first semiconductor fin disposed on a first source/drain region of a first nanosheet transistor device, a second semiconductor fin disposed on a second source/drain region of a second nanosheet transistor device, a first dielectric etch stop layer disposed on the first semiconductor fin, and a second dielectric etch stop layer disposed on the second semiconductor fin. The first semiconductor fin and the second semiconductor fin are of a uniform height.

In embodiments, the integrated circuit further comprises a middle-of-the-line contact disposed on a given one of the first source/drain region and the second source/drain region, and a metal via connecting a backside power rail to the middle-of-the-line contact.

In embodiments, the integrated circuit further comprises a backside power delivery network disposed over the backside power rail.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first semiconductor fin disposed on a first source/drain region of a first nanosheet transistor device;
a second semiconductor fin disposed on a second source/drain region of a second nanosheet transistor device;
a first dielectric etch stop layer disposed on the first semiconductor fin; and
a second dielectric etch stop layer disposed on the second semiconductor fin;
wherein the first semiconductor fin and the second semiconductor fin are of a uniform height.

2. The semiconductor structure according to claim 1, wherein the first semiconductor fin and the first dielectric etch stop layer have a same width, and the second semiconductor fin and the second dielectric etch stop layer have a same width.

3. The semiconductor structure according to claim 1, wherein the first dielectric etch stop layer and the second dielectric etch stop layer each comprises a buried oxide layer.

4. The semiconductor structure according to claim 1, wherein the first dielectric etch stop layer and the second dielectric etch stop layer each comprises an epitaxial oxide layer.

5. The semiconductor structure according to claim 1, wherein the first semiconductor fin and the second semiconductor fin comprise a first backside silicon fin and a second backside silicon fin.

6. The semiconductor structure according to claim 1, further comprising:
a middle-of-the-line contact disposed on a given one of the first source/drain region and the second source/drain region; and
a metal via connecting a backside power rail to the middle-of-the-line contact.

7. The semiconductor structure according to claim 6, further comprising a backside power delivery network disposed over the backside power rail.

8. A semiconductor structure, comprising:
a first silicon fin disposed on a first source/drain region of a first nanosheet transistor device;
a second silicon fin disposed on a second source/drain region of a second nanosheet transistor device;
a first dielectric etch stop layer disposed on the first silicon fin; and
a second dielectric etch stop layer disposed on the second silicon fin;
wherein the first silicon fin and the second silicon fin are disposed between adjacent shallow trench isolation regions; and
wherein the first silicon fin and the second silicon fin are of a uniform height.

9. The semiconductor structure according to claim 8, wherein the first dielectric etch stop layer is a first lattice matched etch stop layer and the second dielectric etch stop layer is a second lattice matched etch stop layer.

10. The semiconductor structure according to claim 9, wherein the first silicon fin and the second silicon fin are each epitaxially grown on the first lattice matched etch stop layer and the second lattice matched etch stop layer.

11. The semiconductor structure according to claim 9, wherein the first lattice matched etch stop layer comprises a first epitaxial oxide layer and the second lattice matched etch stop layer comprises a second epitaxial oxide layer.

12. The semiconductor structure according to claim 11, wherein the first epitaxial oxide layer and the second epitaxial oxide layer each comprises a layer of a mixed rare earth oxide, the mixed rare earth oxide being single crystal and lattice-matched to the first silicon fin and the second silicon fin.

13. The semiconductor structure according to claim 12, wherein the mixed rare earth oxide comprises a compound having a chemical formula (AₓB₁₋ₓ)₂O₃, wherein A represents a first rare earth element and B represents a second rare earth element.

14. The semiconductor structure according to claim 12, wherein the mixed rare earth oxide comprises (Laₓ Y₁₋ₓ)₂O₃ and x is 0.33.

15. The semiconductor structure according to claim 8, wherein the first silicon fin and the second silicon fin are a first backside silicon fin comprise a second backside silicon fin.

16. The semiconductor structure according to claim 8, further comprising:
a middle-of-the-line contact disposed on a given one of the first source/drain region and the second source/drain region; and
a metal via connecting a backside power rail to the middle-of-the-line contact.

17. The semiconductor structure according to claim 16, further comprising a backside power delivery network disposed over the backside power rail.

18. An integrated circuit, comprising:
one or more semiconductor structures, wherein at least one of the one or more semiconductor structures comprises:
a first semiconductor fin disposed on a first source/drain region of a first nanosheet transistor device;
a second semiconductor fin disposed on a second source/drain region of a second nanosheet transistor device;
a first dielectric etch stop layer disposed on the first semiconductor fin; and
a second dielectric etch stop layer disposed on the second semiconductor fin;
wherein the first semiconductor fin and the second semiconductor fin are of a uniform height.

19. The integrated circuit according to claim 18, further comprising:
a middle-of-the-line contact disposed on a given one of the first source/drain region and the second source/drain region; and
a metal via connecting a backside power rail to the middle-of-the-line contact.

20. The integrated circuit according to claim 19, further comprising:
a backside power delivery network disposed over the backside power rail.
